(19) United States
(12) Patent Application Publication
(10) Pub. No.: US 2017/0110341 A1
(43) Pub. Date: Apr. 20, 2017

(54) SEMICONDUCTOR DEVICE MANUFACTURING METHOD

(71) Applicant: DENSO CORPORATION, Kariya-city, Aichi-pref. (JP)

(72) Inventors: Kenji ONODA, Kariya-city (JP); Eiji NOMURA, Kariya-city (JP); Tooru OOTANI, Kariya-city (JP); Akinori ODA, Kariya-city (JP)

(21) Appl. No.: 15/128,127

(22) PCT Filed: Mar. 23, 2015
(86) PCT No.: PCT/JP2015/001623

§ 371 Date: Sep. 22, 2016

(30) Foreign Application Priority Data
Mar. 26, 2014 (JP) 2014-064194

(51) Int. Cl. H01L 21/48; H01L 21/56

(52) U.S. Cl. CPC H01L 21/4882; H01L 21/56; H01L 21/565; H01L 2021/603

(57) ABSTRACT

A pressing unit including a pressing pin is attached to a mold, a semiconductor chip, first and second heat sinks, and solders are disposed in a cavity of the mold, a mold closing state is made, and a reflow is carried out in a state where the first and second heat sinks are pressed against first and second wall surfaces by the pressing pin to form a laminated body. After the laminated body is formed, the pressing pin is pulled out from the cavity, and a resin molded body is formed by injecting a resin.

### CROSS REFERENCE TO RELATED APPLICATIONS

The present disclosure is a U.S. national stage application of International Patent Application No. PCT/JP2015/001623 filed on Mar. 23, 2015 and is based on Japanese Patent Application No. 2014-64194 filed on Mar. 26, 2014, the disclosure of which is incorporated herein by reference.

### TECHNICAL FIELD

The present disclosure relates to a manufacturing method of a semiconductor device having a both-surface heat radiating structure in which heat sinks for radiating a heat of a semiconductor chip are respectively disposed on both sides of the semiconductor chip, and a radiating surface of each of the heat sinks opposite from the semiconductor chip is exposed from a resin molded body.

### BACKGROUND

Conventionally, a manufacturing method described in Patent Literature 1 has been known as a manufacturing method of a semiconductor device having a both-surface heat radiating structure in which heat sinks for radiating a heat of a semiconductor chip are respectively disposed on both sides of the semiconductor chip, and a radiating surface of each of the heat sinks opposite from the semiconductor chip is exposed from a resin molded body.

In Patent Literature 1, at least one of the heat radiating surfaces of the heat sink is embedded at the time of molding. After that, a resin molded body (sealing resin) on the heat radiating surface is, for example, cut with a part of the heat sink so that the heat radiating surface is exposed and a parallelism without a gap between the heating radiating surface and a cooler is secured.

As described above, the method described in Patent Literature 1 needs a cutting process for removing the resin molded body on the heat radiating surface with the part of the heat sink by cutting after the molding process for forming the resin molded body. That is, the number of manufacturing processes increases.

### PATENT LITERATURE

Patent Literature 1: JP 2005-117009 A

### SUMMARY

An object of the present disclosure is to provide a manufacturing method that can manufacture a semiconductor device having a both-surface heat radiating structure by manufacturing processes fewer than the conventional method.

In a manufacturing method of a semiconductor device according to an aspect of the present disclosure, a first heat sink is disposed to a surface of a semiconductor chip, a second heat sink is disposed to a rear surface opposite to the surface, a solder between the semiconductor chip and the first heat sink and a solder between the semiconductor chip and the second heat sink are reflowed to form a laminated body in which the first heat sink, the second heat sink, and the semiconductor chip are integrated. In a state where the laminated body is disposed in a cavity of a mold and the mold is closed in a laminating direction of the laminated body, a resin is injected into the cavity to form a resin molded body that seals the laminated body.

The mold includes, as a wall surface defining the cavity, a first wall surface that faces a heat radiating surface of the first heat sink opposite to the semiconductor chip in the laminating direction and a second wall surface that faces a heat radiating surface of the second heat sink opposite to the semiconductor chip in the laminating direction.

In the forming of the laminated body, a pressing unit that includes a pressing pin and is configured to protrude the pressing pin into the cavity through a hole provided in the mold is attached to the mold. The semiconductor chip, the first heat sink, the second heat sink, and the solders are disposed in the cavity and a mold closing state is made. In the mold closing state, the first heat sink is pressed against the first wall surface and the second heat sink is pressed against the second wall surface by the pressing pin to make a pressing state. The reflow is carried out in the pressing state to form the laminated body. After forming the laminated body, the pressing pin is pulled out from the cavity and the resin molded body is formed.

According to the above-described manufacturing method, using the mold for forming the resin molded body, in the mold closing state, the reflow is carried out while pressing the heat sinks to the corresponding wall surfaces by the pressing pin. Thus, the laminated body having a state in which the heat sinks are pressed against the corresponding wall surfaces can be obtained. Then, the resin molded body is formed using the laminated body. The laminated body and the resin molded body are formed using the same mold, and the mold closing state is the same. Thus, at a time when the formation of the resin molded body ends, the heat radiating surfaces of the heat sinks can be exposed from the resin molded body.

Thus, according to the above-described manufacturing method, a semiconductor device having a both-surface heat radiating structure in which the heat radiating surfaces of the heat sinks are exposed from the resin molded body can be formed. Because cutting after forming the resin molded body is unnecessary, the number of manufacturing processes can be reduced from the conventional method.

### BRIEF DESCRIPTION OF DRAWINGS

The above and other objects, features and advantages of the present disclosure will become more apparent from the following detailed description made with reference to the accompanying drawings. In the drawings:

FIG. 1 is a diagram showing a schematic configuration of a power converter to which a semiconductor device is applied;

FIG. 2 is a plan view showing a schematic configuration of a semiconductor device manufactured by a manufacturing method according to a first embodiment;

FIG. 3 is a cross-sectional view of the semiconductor device taken along line III-III in FIG. 2;

FIG. 4 is a plan view showing a laminated body;

FIG. 5 is a plan view of the laminated body viewed from a lead frame side and in which bonding wires are omitted;

FIG. 6 is a side view showing the laminated body;

FIG. 7 is a cross-sectional view showing a first reflow process;

FIG. 8 is an exploded perspective view showing a second reflow process;

FIG. 9 is a partial cross-sectional view showing the second reflow process;

FIG. 10 is a partial cross-sectional view showing a molding process;

FIG. 11 is an exploded perspective view showing a second reflow process in a manufacturing method according to a second embodiment; and

FIG. 12 is a cross-sectional view showing a schematic configuration of a semiconductor device manufactured by the manufacturing method according to the second embodiment.

### DETAILED DESCRIPTION

Embodiments of the present disclosure will be described below with reference to the accompanying drawings. In each of the following embodiments, the same reference sign is given to the same or equivalent parts in the drawings. A laminating direction of each heat sink and a semiconductor chip is indicated as a Z-direction. A direction orthogonal to the Z-direction and in which main terminals and control terminals extend is indicated as a Y-direction. Furthermore, a direction orthogonal to both of the Y-direction and the Z-direction is indicated as an X-direction. A planar shape means a shape along a plane defined by the X-direction and the Y-direction unless otherwise noted.

### First Embodiment

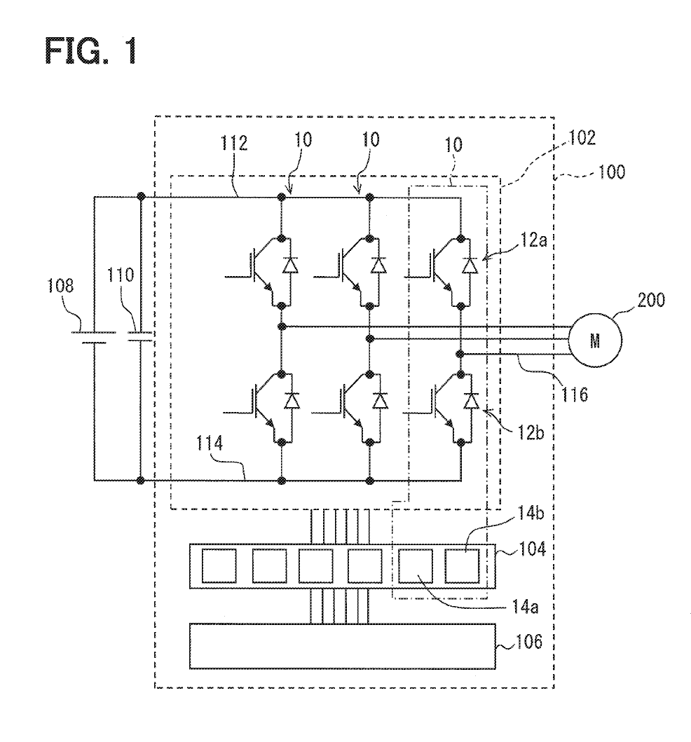

First, an example of a power converter to which a semiconductor device shown below is applied will be described based on FIG. 1.

A power converter 100 shown in FIG. 1 includes an inverter 102 for driving a motor 200 for vehicle traveling, a driver 104 for driving the inverter 102, and a microcomputer 106 outputting a driving signal to the inverter 102 via the driver 104. The power converter 100 is equipped, for example, in an electric vehicle or a hybrid vehicle.

The inverter 102 has upper and lower arms connected between a positive electrode (high potential side) and a negative electrode (low potential side) of a direct current power supply 108 for three phases. Each of the arms includes an IGBT element and a FWD element connected in antiparallel with the IGBT element. The inverter 102 converts a direct current power to a three-phase alternating current and outputs the three-phase alternating current to the motor 200.

A reference sign 110 shown in FIG. 1 indicates a smoothing capacitor. The positive electrode of the direct current power supply 108 is connected with a high potential power line 112, and the negative electrode of the direct current power supply 108 is connected with a low potential power line 114. Collector electrodes of the IGBT elements on the upper arm side are connected with the high potential power line 112, and emitter electrodes of the IGBT elements on the lower arm side are connected with the low potential power line 114. Emitter electrodes of the IGBT elements on the upper arm side and collector electrodes of the IGBT elements on the low arm side are connected with output lines 116 to the motor 200.

The driver 104 has chips corresponding to respective arms, and each of the chips includes a circuit for driving the corresponding arm.

The microcomputer 106 outputs the driving signal (PWM signal) to the inverter 102 via the driver 104 to control driving of the IGBT element. The microcomputer 106 includes a ROM storing programs in which various control processes to be executed are described, a CPU executing various operation processes, a RAM temporarily storing operation process results and various data.

The microcomputer 106 receives detection signals from a current sensor and a rotation sensor, which are not shown, and generates the driving signal for driving the motor 200 based on a torque command value given from outside and the detection signals of the above-described sensors. The six IGBT elements in the inverter 102 are driven based on the driving signal, and a drive current is supplied from the direct current power supply 108 to the motor 200 via the inverter 102. As a result, the motor 200 is driven so as to generate a desired driving torque. Alternatively, an electric current by a power generated by the motor 200 is rectified by the inverter 102 and the direct current power supply 108 is charged.

A semiconductor device 10 includes the upper and lower arms forming the inverter 102 for one phase. In the present embodiment, the semiconductor device 10 includes a semiconductor chip 12a on the upper arm side in which the IGBT element and the FWD element are formed, and a semiconductor chip 12b on the lower arm side in which the IGBT element and the FWD element are formed similarly. In addition, the semiconductor device 10 includes a driver IC 14a on the upper arm side corresponding to the semiconductor chip 12a and a driver IC 14b on the low arm side corresponding to the semiconductor chip 12b. The driver ICs 14a, 14b constitute the driver 104 and, for example, MOSFETs are formed in semiconductor chips for driving the IGBT elements formed in the corresponding semiconductor chips 12a, 12b.

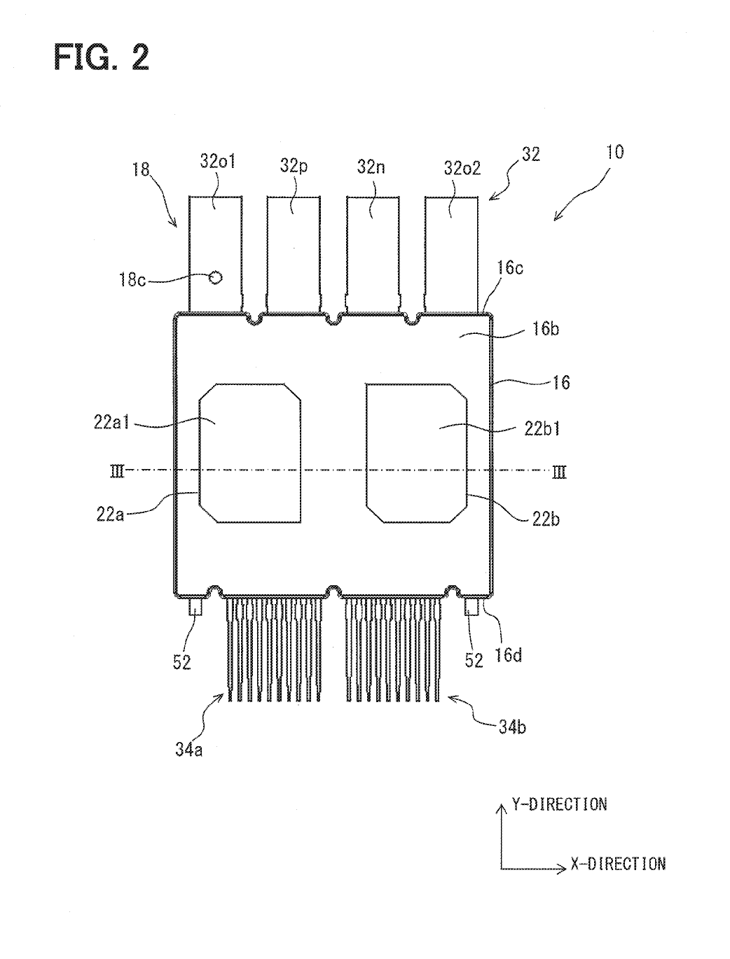

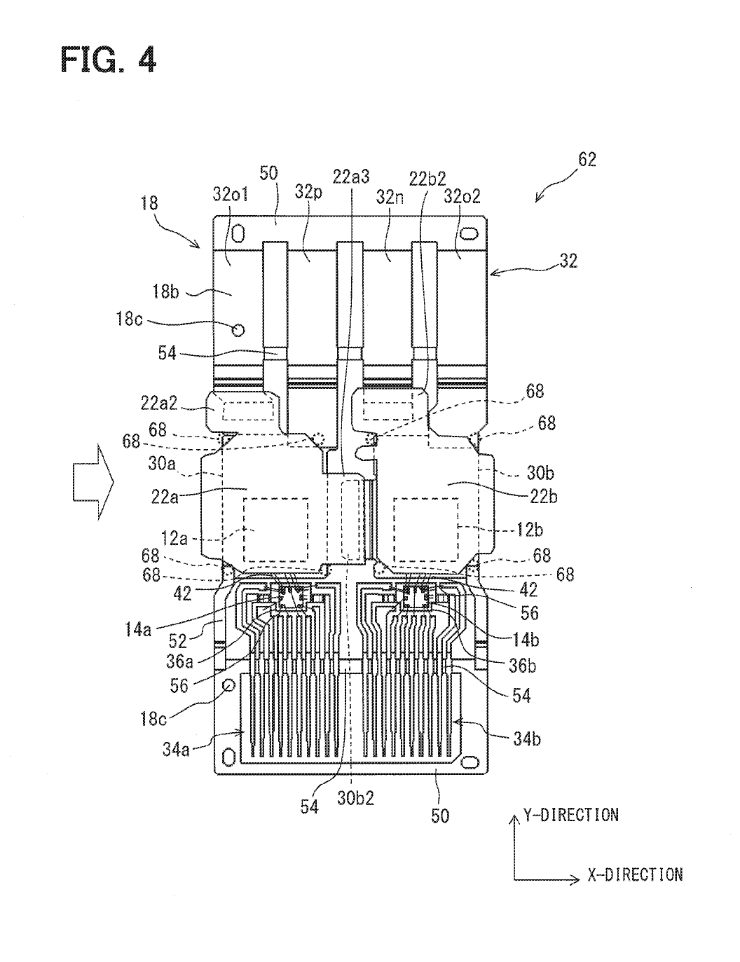

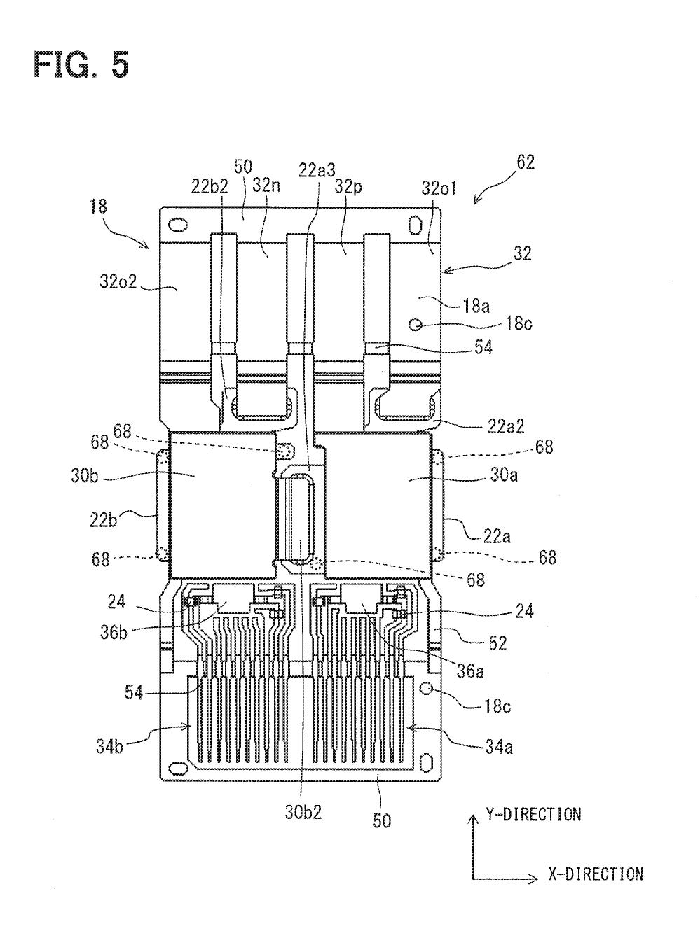

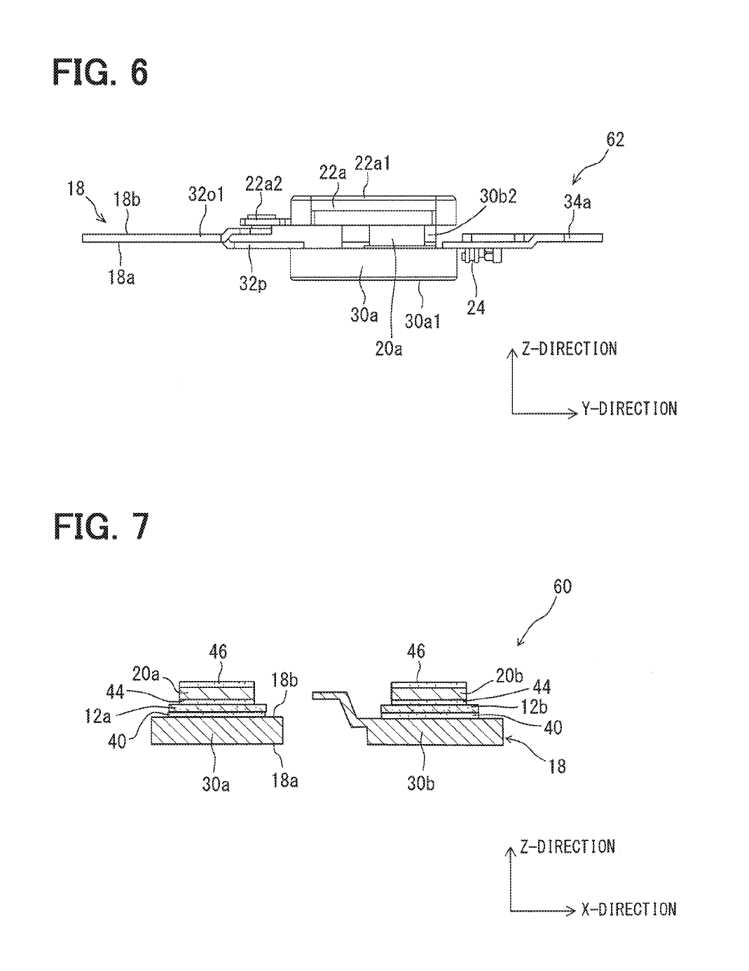

Next, a schematic configuration of the semiconductor device 10 formed by a manufacturing method according to the present embodiment will be described with reference to FIG. 2 to FIG. 6. FIG. 4 to FIG. 6 show a laminated body. In other words, FIG. 4 to FIG. 6 show a state before unnecessary parts of a lead frame are removed. In FIG. 5, bonding wires are omitted. FIG. 6 is a side view viewed from a direction of a blank arrow shown in FIG. 4.

As shown in FIG. 2 to FIG. 6, the semiconductor device 10 includes a resin molded body 16, a lead frame 18, terminals 20a, 20b, second heat sinks 22a, 22b, and passive components 24 in addition to the semiconductor chips 12a, 12b and the driver ICs 14a, 14b described above.

The semiconductor device 10 includes the two semiconductor chips 12a, 12b of the semiconductor chip 12a on the upper arm side and the semiconductor chip 12b on the lower arm side, and is a so-called 2-in-1 package in which the semiconductor chips 12a, 12b are sealed with the resin molded body 16.

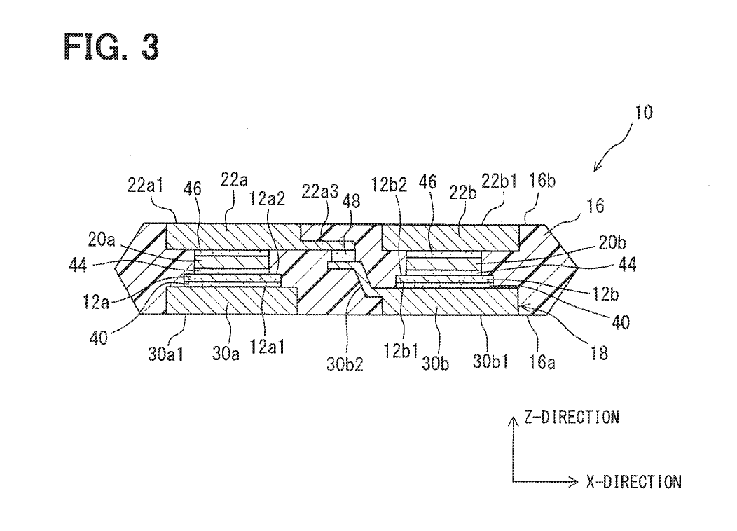

The semiconductor chips 12a, 12b have the same chip configuration, have the same planar shapes and sizes, and have the same thicknesses in the Z-direction. As shown in FIG. 3 and FIG. 4, the semiconductor chips 12a, 12b are arranged in the X-direction and are arranged at substantially the same position in the Z-direction, that is, are arranged in parallel. In the Z-direction, forming surfaces of collector electrodes of the semiconductor chips 12a, 12b are on the same side, and forming surfaces of emitter electrodes and control electrodes are on the same surfaces. Hereafter, the forming surface of the collector electrode of the semiconductor chip 12a is indicated as a surface 12a1, and a surface opposite from the surface 12a1, that is, the forming surface of the emitter electrode and the control electrode is indicated as a rear surface 12a2. Similarly, the forming surface of the collector electrode of the semiconductor chip 12b is indicated as a surface 12b1, and a surface opposite from the surface 12b1, that is, the forming surface of the emitter electrode and the control electrode is indicated as a rear surface 12b2.

The resin molded body 16 is made of a resin material having an electrical insulation property. In the present embodiment, the resin molded body 16 is made of epoxy resin by transfer molding. The resin molded body 16 has an approximately rectangular shape and has a surface 16a and a rear surface 16b opposite from the surface 16a in the Z-direction. The surface 16a and the rear surface 16b are flat surfaces approximately perpendicular to the Z-direction. The semiconductor chips 12a, 12b and the driver ICs 14a, 14b are sealed with the resin molded body 16.

The lead frame 18 is formed by punching a metal plate and bending partially, and has a surface 18a and a rear surface 18b opposite from the surface 18a in the Z-direction. The lead frame 18 is formed using at least a metal material. For example, a metal material having a high thermal conductivity and a high electrical conductivity, such as copper, copper alloy, or aluminum alloy can be employed. The lead frame 18 includes first heat sinks 30a, 30b, a plurality of main terminals 32, a plurality of control terminals 34a, 34b, and islands 36a, 36b.

The first heat sinks 30a, 30b have functions of radiating heat generated at the semiconductor chips 12a, 12b and functions of electric connection. The first heat sinks 30a, 30b are disposed at substantially the same position in the Z-direction, that is, are disposed in parallel while being separated from each other.

The first heat sink 30a, 30b are disposed to a side of the surfaces 12a1, 12b1 of the semiconductor chips 12a, 12b. The first heat sinks 30a, 30b have approximately rectangular planar shape and have substantially the same thickness. Sizes of the semiconductor chips 12a, 12b along a plane defined by the X-direction and the Y-direction are larger than the semiconductor chips 12a, 12b so as to contain the corresponding semiconductor chips 12a, 12b.

Above the rear surface 18b in the first heat sink 30a, the semiconductor chip 12a on the upper arm side is disposed so that the surface 12a1 faces the rear surface 18b. Then, the collector electrode formed on the surface 12a1 and not shown is connected with first heat sink 30a via a solder 40. Similarly, above the rear surface 18b in the first heat sink 30b, the semiconductor chip 12b on the lower arm side is disposed so that the surface 12b1 faces the rear surface 18b. Then, the collector electrode formed on the surface 12b1 and not shown is connected with the first heat sink 30b via the solder 40.

In the surface of the first heat sink 30a, a part on the rear surface 18b side facing the semiconductor chip 12a and side surfaces are covered by the resin molded body 16. On the other hand, a part on the surface 18a side is exposed from the resin molded body 16. In this way, the part of the surface 18a exposed from the resin molded boy 16 becomes a heat radiating surface 30a1 of the first heat sink 30a. In the present embodiment, the heat radiating surface 30a1 is substantially flush with the surface 16a of the resin molded body 16. Note that flush means more than two planes are on the same plane and there is no difference in level. In the surface of the first heat sink 30b, a part on the rear surface 18b side facing the semiconductor chip 12b and side surfaces are covered by the resin molded body 16. On the other hand, a part on the surface 18a side is exposed from the resin molded body 16. In this way, the part of the surface 18a exposed from the resin molded boy 16 becomes a heat radiating surface 30b1 of the first heat sink 30b. The heat radiating surface 30b1 is also substantially flush with the surface 16a of the resin molded body 16. The solder 40 is also sealed by the resin molded body 16.

On the other hand, the second heat sinks 22a, 22b are disposed to the rear surfaces 12a2, 12b2 of the semiconductor chips 12a, 12b in the Z-direction via terminals 20a, 20b.

As shown in FIG. 4, the terminals 20a, 20b are disposed to secure predetermined intervals between the semiconductor chips 12a, 12b and the second heat sinks 22a, 22b so as to connect bonding wires 42 to the control electrodes (pads) of the semiconductor chips 12a, 12b. Because the terminals 20a, 20b thermally and electrically connects the semiconductor chips 12a, 12b and the second heat sinks 22a, 22b, a metal material having at least a high thermal conductivity and a high electrical conductivity may be used as a material of the terminals 20a, 20b.

The terminals 20a, 20b have shapes and sizes corresponding to the emitter electrodes of the corresponding semiconductor chips 12a, 12b and have rectangular parallelepiped shapes in the present embodiment. The terminals 20a on the upper arm side faces the emitter electrode of the semiconductor chip 12a and is connected with the emitter electrode via a solder 44. Similarly, the terminal 20b on the lower arm side faces the emitter electrode of the semiconductor chip 12b and is connected with the emitter electrode via the solder 44. The terminals 20a, 20b, the bonding wire 42, and the solder 44 are also sealed by the resin molded body 16.

A surface of the terminal 20a opposite from the semiconductor chip 12a is connected with the second heat sink 22a on the upper arm side via a solder 46. Similarly, a surface of the terminal 20b opposite from the semiconductor chip 12b is connected with the second heat sink 22b on the lower arm side via the solder 46. The second heat sinks 22a, 22b are also made of at least a metal material having a high thermal conductivity and a high electrical conductivity to secure a thermal conductivity and an electrical conductivity in a manner similar to the first heat sinks 30a, 30b. The second heat sinks 22a, 22b have substantially the same thickness and are disposed at substantially the same position in the Z-direction, that is, are disposed in parallel while being separated from each other. The second heat sinks 22a, 22b are disposed in such a manner that the semiconductor chips 12a, 12b are contained in a facing region with the corresponding first heat sinks 30a, 30b in the plane defined by the X-direction and the Y-direction. The first heat sinks 30a, 30b and the second heat sinks 22a, 22b have portions which are not opposed to each other so that the first heat sinks 30a, 30b can be pressed against a cavity wall surface behind and the second heat sinks 22a, 22b can be pressed against the cavity wall surface behind by pressing pins 66a in a reflow process described below. In other words, the first heat sinks 30a, 30b, and the second heat sinks 22a, 22b have portions with which the pressing pins come into contact.

In the surface of the second heat sink 22a, a facing surface to the semiconductor chip 12a (the terminal 20a) and side surfaces are covered by the resin molded body 16. On the other hand, a surface opposite from the facing surface is exposed from the resin molded body 16. In this way, the surface exposed from the resin molded body 16 becomes a heat radiating surface 22a1 of the second heat sink 22a. In the present embodiment, the heat radiating surface 22a1 is substantially flush with the rear surface 16b of the resin molded body 16. Similarly, in the surface of the second heat sink 22b, a facing surface to the semiconductor chip 12b (the terminal 20b) and the side surfaces are covered by the resin molded body 16. On the other hand, a surface opposite from the facing surface is exposed from the resin molded body 16. In this way, the surface exposed from the resin molded body 16 becomes a heat radiating surface 22b1 of the second heat sink 22b. The heat radiating surface 22a1 is also substantially flush with the rear surface 16b of the resin molded body 16. The solder 46 is also sealed by the resin molded body 16.

As shown in FIG. 4 and FIG. 5, the second heat sinks 22a, 22b have approximately rectangular planar shapes in which two sides are substantially parallel to the X-direction and the other two sides are substantially parallel to the Y-direction. In the second heat sink 22a on the upper arm side, from a side substantially parallel to the X-direction, a protruding portion 22a2 protrudes in the Y-direction. Similarly, from the second heat sink 22b on the lower arm side, a protruding portion 22b2 protrudes in the same side with the protruding portion 22a2. The protruding portions 22a2, 22b2 are portions electrically connected with a part of the plurality of main terminals 32. The protruding portions 22a2, 22b2 are thinner than the second heat sinks 22a, 22b. The protruding portions 22a2, 22b2 are also sealed by the resin molded body 16.

In the first heat sink 30b on the lower arm side, from an end in the X-direction adjacent to the upper arm, a protruding portion 30b2 protrudes toward the upper arm. On the other hand, in the second heat sink 22a on the upper arm side, from an end in the X-direction adjacent to the lower arm, a protruding portion 22a3 protrudes toward the lower arm. The protruding portions 22a3, 30b2 are connected via a solder 48. By the connection, the emitter electrode of the IGBT element on the upper arm side and the collector electrode of the IGBT element on the lower arm side are electrically connected, and the upper and lower arms have an approximately N-shape as shown in FIG. 3. The connection structure of a relay portion electrically relaying the first heat sink 30b on the lower arm side and the second heat sink 22a on the upper arm side is not limited to the above-described example. A configuration in which only one of the heat sinks 22a, 30b have a protruding portion can also be employed.

The main terminals 32 of the lead frame 18 extend outward of the resin molded body 16 from a side surface 16c of the resin molded body 16 having a rectangular planar shape. In other words, a part of the terminals are sealed by the resin molded body 16. The terminals 32 separately extend in the Y-direction and are arranged in the X-direction. Furthermore, in the Z-direction, the terminals 32 are bent in the middle in a longitudinal direction so as to extend from positions between the surface 16a and the rear surface 16b.

The main terminals 32 include a power supply terminal 32p, a ground terminal 32n, and output terminals 32o1, 32o2. The power supply terminal 32p is a terminal for connecting the collector electrode of the semiconductor chip 12a to the high potential power line 112 (so-called P terminal). As shown in FIG. 4 and FIG. 5, the power supply terminal 32p is connected to the first heat sink 30a on the upper arm side, and extends in the Y-direction from a side of the first heat sink 30a having the rectangular planar shape.

The ground terminal 32n is a terminal for connecting the emitter electrode of the semiconductor chip 12b to the low potential power line 114 (so-called N terminal). The ground terminal 32n is disposed next to the power supply terminal 32p. The ground terminal 32n is electrically connected with the protruding portion 22b2 of the second heat sink 22b on the lower arm side via a solder which is not shown.

The output terminal 32o1 is a terminal for connecting the emitter electrode of the semiconductor chip 12a to the output line 116 (so-called O terminal). The output terminal 32o1 is disposed next to the power supply terminal 32p so as to sandwich the power supply terminal 32p with the ground terminal 32n. The output terminal 32o1 is electrically connected with the protruding portion 22a2 of the second heat sink 22a on the upper arm side via a solder which is not shown.

The output terminal 22o2 is a terminal for connecting the collector electrode of the semiconductor chip 12b to the output line 116 (so-called O terminal). The output terminal 22o2 is connected with the first heat sink 30b on the lower arm side and extends in the Y-direction from one side of the first heat sink 30b having the approximately rectangular planar shape.

The control terminals 34a, 34b extend outward of the resin molded body 16 from a side surface 16d opposite form the side surface 16c of the resin molded body 16. In other words, a part of the control terminals 34a, 34b are sealed by the resin molded body 16. The control terminals 34a, 34b separately extend in the Y-direction and are arranged in the X-direction. Furthermore, in the Z-direction, the control terminals 34a, 34b are bent in the middle in a longitudinal direction so as to extend from positions between the surface 16a and the rear surface 16b.

The control terminals 34a, 34b include terminals for the gate electrodes of the IGBT elements, for temperature sensing, for electric-current sensing, for a Kelvin emitter, for the power supply, for the ground, and for error check. In addition, a part of the control terminals 34a, 34b are connected with corresponding islands 36a, 36b.

A reference sign 50 shown in FIG. 2, FIG. 4, and FIG. 5 indicates a peripheral frame of the lead frame 18, and a reference sign 52 indicates a hanging lead for connecting the first heat sinks 30a, 30b to the peripheral frame 50. A reference sign 54 indicates a tie bar. In a state of the semiconductor device 10, the peripheral frame 50 and the tie bar 54 are removed from the lead frame 18.

The driver IC 14a on the upper arm side is mounted to the island 36a on the upper arm side via a solder which is not shown. Similarly, the driver IC 14b is mounted to the island 36b on the lower arm side via a solder which is not shown. On surfaces of the driver ICs 14a, 14b opposite from the islands 36a, 36b, electrodes (pads) are formed, and the electrodes and the control electrodes of the semiconductor chips 12a, 12b are connected via the bonding wires 42. In addition, the driver ICs 14a, 14b and the corresponding control terminals 34a, 34b are connected by bonding wires 56.

As shown in FIG. 5 and FIG. 6, the passive components 24 such as a chip resistor and a chip capacitor are mounted to the control terminals 34a, 34b via joint members (for example, a solder) which is not shown. The passive components 24 are mounted, for example, for restricting noises transmitted from the control terminals 34a, 34b to the driver ICs 14a, 14b. In the present embodiment, the passive components 24 are chip components having two terminals and are mounted so as to bridge the two control terminals 34a, 34b adjacent to each other. The passive components 24 are mounted to the surface 18a of the lead frame 18.

The semiconductor device 10 having the above-described configuration is cooled by cooling devices having passages in which a coolant flows. In detail, the cooling devices are arranged on both sides of the semiconductor device 10 in the Z-direction, and the semiconductor device 10 can radiate heat from the heat radiating surfaces 22a1, 22b1, 30a1, 30b1 to the cooling devices disposed on the both sides.

Next, based on FIG. 7 to FIG. 10, an example of a manufacturing method of the above-described semiconductor device 10 will be described. In the manufacturing method described below, an example in which a reflow is carried out in two stages will be described.

First, each component constituting the semiconductor device 10 is prepared. Specifically, the semiconductor chips 12a, 12b, the driver ICs 14a, 14b, the lead frame 18, the terminals 20a, 20b, the second heat sinks 22a, 22b, and the passive components 24 are prepared. At that time, the lead frame 18 integrally including the first heat sinks 30a, 30b, the main terminals 32, the control terminals 34a, 34b, and the islands 36a, 36b is prepared.

Next, a first reflow process is carried out. In the first reflow process, as shown in FIG. 7, the solder 40 disposed between the semiconductor chips 12a, 12b and the corresponding first heat sinks 30a, 30b and the solder 44 disposed between the semiconductor chips 12a, 12b and the corresponding terminals 20a, 20b are reflowed. Besides, the solder disposed between the driver ICs 14a, 14b and the corresponding islands 36a, 36b is also reflowed. Then, a connection body 60 in which the semiconductor chips 12, the driver ICs 14a, 14b, the lead frame 18 and the terminals 20a, 20b are integrated is formed.

For example, in a preparing process, the solders 44, 46 are previously applied (preliminary solder) to both surfaces of each of the terminals 20a, 20b. Next, the solder 40 is disposed on portions of the first heat sinks 30a, 30b on the rear surface 18b of the lead frame 18, and the semiconductor chips 12a, 12b are disposed on the solder 40 so that the surfaces 12a1, 12b1 face the solder 40. Furthermore, the terminals 20a, 20b are disposed so as to face the emitter electrodes of the semiconductor chips 12a, 12b. On the other hand, the driver ICs 14a, 14b are respectively disposed to portions of the islands 36a, 36b on the rear surface 18b via the solder. The solders 40, 44, 46 and the solders on the islands 36a, 36b are reflowed in this laminating state to form the above-described connection body 60.

Next, a wire bonding process is carried out. The control electrodes of the semiconductor chips 12a, 12b and the corresponding electrodes of the driver ICs 14a, 14b are respectively connected by the bonding wires 42. In addition, the electrodes of the driver ICs 14a, 14b and the corresponding control terminals 34a, 34b are respectively connected by the bonding wires 56.

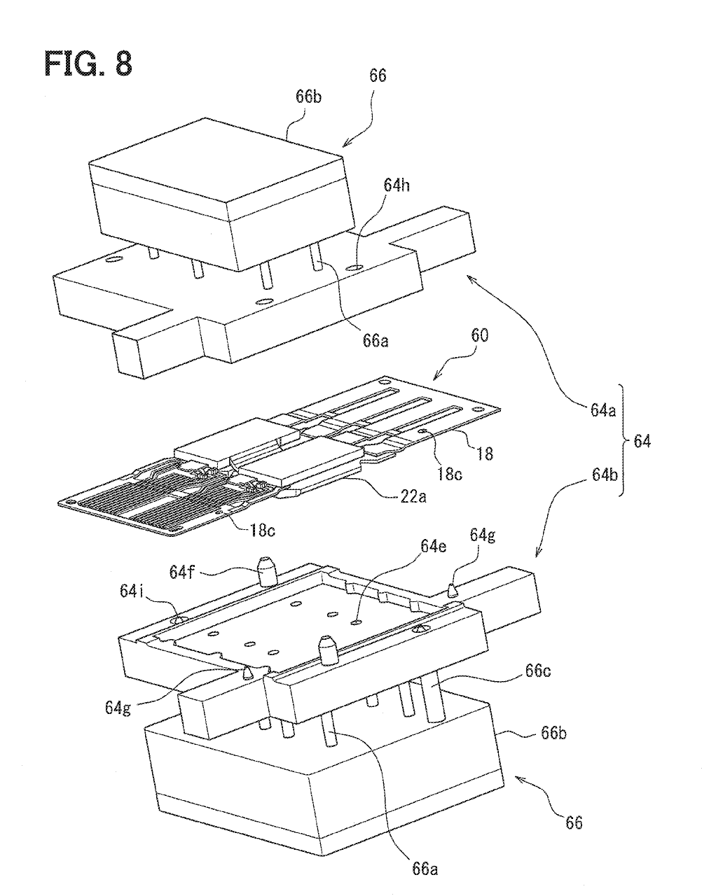

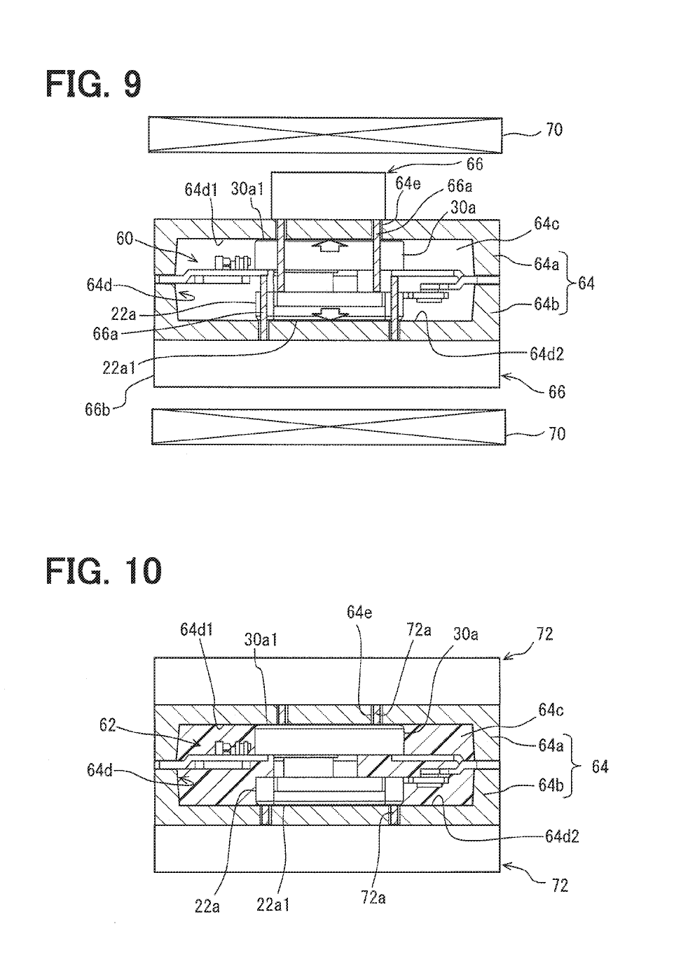

Next, a second reflow process is carried out. In the second reflow process, as shown in FIG. 8 and FIG. 9, the connection body 60 is reversed in the Z-direction from a state of the first reflow process, and the reversed connection body 60 is disposed on the second heat sinks 22a, 22b. Namely, the first heat sinks 30a, 30b are disposed to the surfaces 12a1, 12b1 of the semiconductor chips 12a, 12b, and the second heat sinks 22a, 22b are disposed to the rear surfaces 12a2, 12b2. Then, the solder 40 between the semiconductor chips 12a, 12b and the first heat sinks 30a, 30b, and the solder 46 between the semiconductor chips 12a, 12b and the second heat sinks 22a, 22b are reflowed so as to form a laminated body 62 in which a pair of heat sinks 22a, 22b, 30a, 30b and the semiconductor chips 12a, 12b are integrated.

In the present embodiment, the reflow is carried out with a metal mold 64 and a pressing unit 66 in a molding process described below. The metal mold 64 corresponds to a mold.

The metal mold 64 includes an upper mold 64a and a lower mold 64b which are openable in the Z-direction. In addition, the metal mold 64 includes a first wall surface 64d1 and a second wall surface 64d2 as a wall surface 64d of a cavity 64c formed by closing the upper mold 64a and the lower mold 64b. The first wall surface 64d1 is a portion facing the heat radiating surfaces 30a1, 30b1 of the first heat sinks 30a, 30b in the Z-direction, and forms a bottom of a depressed portion that is formed in the upper mold 64a to define the cavity 64c. On the other hand, the second wall surface 64d2 is a portion facing the heat radiating surfaces 22a1, 22b1 of the second heat sinks 22a, 22b in the Z-direction, and forms a bottom of a depressed portion that is formed in the lower mold 64b to define the cavity 64c.

In each of the upper mold 64a and the lower mold 64b, a plurality of through holes 64e is formed. The through holes 64e correspond to holes provided in the mold. In the through holes 64e, pressing pins 66a described below are inserted. The through holes 64e formed in the upper mold 64a are formed along the Z-direction and ends of the through holes 64e open to the first wall surface 64d1. The through holes 64e open at positions which do not overlap with the lead frame 18 and overlap with the second heat sinks 22a, 22b in a plane defined by the X-direction and the Y-direction. Similarly, the through holes 64e formed in the lower mold 64b are formed along the Z-direction and ends of the through holes 64e open to the second wall surface 64d2. The through holes 64e open at positions which do not overlap with the second heat sinks 22a, 22b and overlap with the lead frame 18 in a plane defined by the X-direction and the Y-direction.

The metal mold 64 further includes positioning pins 64f, 64g, positioning holes 64h, and through holes 64i. The positioning pins 64f protrude from a division surface of the metal mold 64 in the lower mold 64b toward the upper mold 64a. The positioning pins 64f and positioning pins 66c described below are inserted into the positioning holes 64h formed in the upper mold 64a to position the upper mold 64a and the lower mold 64b. The positioning pins 64g are provided on the division surface of the lower mold 64b to position the lead frame 18 (the connection body 60). When the positioning pins 64f are inserted into positioning holes 18c of the lead frame 18, the position of the lead frame 18 is determined with respect to the metal mold 64. The through holes 64i are formed to correspond to the positions pins 66c so that the positioning pins 66c described below are inserted.

The pressing unit 66 includes pressing pins 66a to press the heat sinks 22a, 22b, 30a, 30b against the corresponding wall surfaces 64d1, 64d2. In the present embodiment, the pressing pins 66a have spring property in the Z-direction. The pressing pins 66a protrude from a body portion 66b in the Z-direction. The body portion 66b is formed so that the pressing pins 66a are protrudable in the cavity 64c through the through holes 64e in the metal mold 64. In addition, the pressing unit 66 is detachable from the metal mold 64.

The pressing unit 66 further includes the positioning pins 66c. The positioning pins 66c protrude from the same surface of the body portion 66b with the pressing pins 66a, and are inserted into the positioning holes 64h in the upper mold 64a through the through holes 64i in the lower mold 64b. In the present embodiment, the upper mold 64a and the lower mold 64b are positioned by the two positioning pins 64f and two positioning pins 66c. The positioning pins 64f, 66c are respectively disposed at vertices of a planar rectangle to surround the cavity 64c. The positioning pins 64f are disposed diagonally, and the positioning pins 66c are disposed diagonally.

In a state of closing the mold shown in FIG. 9, the first heat sinks 30a, 30b are pressed against the first wall surface 64d1 behind by the pressing pins 66a protruding from the second wall surface 64d2 of the lower mold 64b. The pressing pins 66a press portions of the lead frame 18 that do not overlap with the second heat sinks 22a, 22b so as to press the first heat sinks 30a, 30b against the first wall surface 64d1. For example, the pressing pins 66a may press the first heat sinks 30a, 30b while coming in contact with only the first heat sinks 30a, 30b, or may press the first heat sinks 30a, 30b while coming in contact with portions of the lead frame 18 other than the first heat sinks 30a, 30b. It is preferable that the pressing pins 66a come in contact with the first heat sinks 30a, 30b in terms of pressing the first heat sinks 30a, 30b against the first wall surface 64d1 behind. Even in a case where the pressing pins 66a come in contact with portions other than the first heat sinks 30a, 30b, it is preferable that the pressing pins 66a come in contact with positions as close as possible to the first heat sinks 30a, 30b.

In the present embodiment, portions of the lead frame 18 indicated by dashed lines in FIG. 4 are pressed portions 68 by the pressing pins 66a. Four pressed portions 68 are set with respect to each of the first heat sinks 30a, 30b. The four pressed portions 68 set with respect to each of the first heat sinks 30a, 30b are vertices of a planar rectangle. In the pressed portions 68 to the first heat sink 30a, two pressed portions 68 located diagonally are set in the vicinity of corner portions of the first heat sink 30a having the planar rectangular shape. In the remaining pressed portions 68, one is set in the vicinity of an end portion of the hanging lead 52 adjacent to first heat sink 30a, and the other is set in the vicinity of a connecting end of the power supply terminal 32p with the first heat sink 30a. By the four pressed portions 68, the position of the second heat sink 22a is determined in a plane defined by the X-direction and the Y-direction. In other words, the pressing pins 66a corresponding to the first heat sink 30a also have a function of positioning the second heat sink 22a with respect to the first heat sink 30a.

On the other hand, in the pressed portion 68 set to the first heat sink 30b, three pressed portions 68 are set in the vicinity of corner portions of the first heat sink 30b having the planar rectangular shape. The remaining pressed portion 68 is set in the vicinity of an end portion of the hanging lead 52 adjacent to the first heat sink 30b. By the four pressed portions 68, the position of the second heat sink 22b is determined in a plane defined by the X-direction and the Y-direction. In other words, the pressing pins 66a corresponding to the first heat sink 30b also have a function of positioning the second heat sink 22b with respect to the first heat sink 30b.

In addition, portions of the second heat sinks 22a, 22b indicated by dashed lines in FIG. 5 are pressed portions 68 by the pressing pins 66a. Three pressed portions 68 are set with respect to each of the second heat sinks 22a, 22b. The pressed portions 68 set to the second heat sink 22a are disposed on both sides of the first heat sink 30a in the X-direction. In addition, two in three are set in the vicinity of end portion of the second heat sink 22a adjacent to the island 36a, and the remaining one is set in the vicinity of an end portion adjacent to the main terminals 32. The pressed portions 68 set to the second heat sink 22b are also disposed on both sides of the first heat sink 30b in the X-direction. In addition, two in three are set in the vicinity of end portion of the second heat sink 22b adjacent to the main terminals 32, and the remaining one is set in the vicinity of an end portion adjacent to the island 36b.

In the second reflow process, the above-described pressing unit 66 is attached to the metal mold 64. Then, the connection body 60 is reversed in the Z-direction from the state of the first reflow, the connection body 60 in the reversed state is disposed on the second heat sinks 22a, 22b, and the second heat sinks 22a, 22b and the connection body 60 are disposed in the cavity 64c. At that time, the solder 48 is disposed also on the protruding portion 30b2 that forms the relay portion, and the protruding portion 22a3 is stacked on the solder 48. Furthermore, on the surface 18a of the lead frame 18, the passive components 24 are disposed at predetermined positions of the control terminals 34a, 34b.

The metal mold 64 is closed in this arrangement state, and in the mold closing state, the pressing pins 66a press the first heat sinks 30a, 30b against the first wall surface 64d1, and press the second heat sinks 22a, 22b against the second wall surface 64d2. Then, in this pressing state, each of the solders 40, 44, 46, 48 are reflowed by heating with a heat source 70, and the laminated body 62 is formed. In addition, by the heat of reflow, the passive components 24 are mounted to the control terminals 34a, 34b via the joint members.

In the present embodiment, by pressing with the pressing pins 66a, the heat radiating surfaces 30a1, 30b1 of the first heat sinks 30a, 30b are brought into contact with the first wall surface 64d1, and the heat radiating surfaces 22a1, 22b1 are brought into contact with the second wall surface 64d2. In this pressing state, the reflow is carried out.

After the second reflow process ends, the pressing pins 66a are pulled out from the cavity 64c, and the molding process is carried out in a state where the through holes 64e of the metal mold 64 are closed.

In the present embodiment, the pressing unit 66 is removed from the metal mold 64, and as shown in FIG. 10, the metal mold 64 is set to a molding machine 72. The molding machine 72 has ejector pins 72a for closing the through holes 64e. The ejector pins 72a on the upper mold 64a side are inserted into the through holes 64e of the upper mold 64a so that protruding ends of the ejector pins 72a are substantially flush with the first wall surface 64d1. On the other hand, the ejector pins 72a on the lower mold 64b side are inserted into the through holes 64e of the lower mold 64b so that protruding ends of the ejector pins 72a are substantially flush with the second wall surface 64d2. Accordingly, a resin leakage at molding can be restricted.

Then, the laminated body 62 is disposed in the cavity 64c of the metal mold 64, and the metal mold 64 is closed. The molding process may be carried out without taking the laminated body 62 formed in the second reflow process out from the metal mold 64, or the laminated body 62 may be set again in the cavity 64c after taking out.

In the present embodiment, the heat radiating surfaces 30a1, 30b1 of the first heat sinks 30a, 30b come into contact with the first wall surface 64d1, and the heat radiating surfaces 22a1, 22b1 of the second heat sinks 22a, 22b come into contact with the second wall surface 64d2. Thus, when the resin molded body 16 is formed by injecting a resin in the cavity 64c in this mold closing state, the heat radiating surfaces 30a1, 30b1 can be exposed from the surface 16a, and the heat radiating surfaces 22a1, 22b1 can be exposed from the rear surface 16b. In the present embodiment, both the wall surfaces 64d1, 64d2 are flat surfaces substantially perpendicular to the Z-direction, and the heat radiating surfaces 22a1, 22b1, 30a1, 30b1 are also flat. Thus, the heat radiating surfaces 30a1, 30b1 are substantially flush with the surface 16a, and the heat radiating surfaces 22a1, 22b1 are substantially flush with the rear surface 16b. In the present embodiment, the resin molded body 16 is formed by a transfer molding method using epoxy resin.

After the molding process, the laminated body 62 sealed by the resin molded body 16 is pushed up with the ejector pins 72a to be taken out from the metal mold 64. Then, unnecessary portions of the lead frame 18, that is, the peripheral frame 50 and the tie bar 54 are removed to obtain the semiconductor device 10.

Next, effects of the manufacturing method of the semiconductor device according to the present embodiment will be described.

According to the present embodiment, the reflow is carried out in a state where each of the heat sinks 22a, 22b, 30a, 30b are pressed by the pressing pins 66a against the corresponding wall surface 64d1, 64d2 in the mold closing state using the metal mold 64 in the molding process. Thus, the laminated body 62 in which the first heat sinks 30a, 30b are pressed against the first wall surface 64d1, and the second heat sinks 22a, 22b are pressed against the second wall surface 64d2 can be obtained. Then, the molding process is carried out using the laminated body 62. The metal mold 64 in the reflow process and the molding process is the same, and the mold closing state is also the same. Thus, at a time when the molding process ends, the heat radiating surfaces 30a1, 30b1 of the first heat sinks 30a, 30b can be exposed from the surface 16a of the resin molded body 16. Similarly, the heat radiating surfaces 22a1, 22b1 of the second heat sinks 22a, 22b can be exposed from the rear surface 16b of the resin molded body 16.

In this way, by the manufacturing method according to the present embodiment, the semiconductor device 10 having a both-surface heat radiating structure in which the heat radiating surfaces 22a1, 22b1, 30a1, 30b1 are exposed from the resin molded body 16 can be formed without cutting. Because a cutting after the molding process is unnecessary, the number of manufacturing process can be reduced from the conventional method.

Especially, in the present embodiment, the first heat sinks 30a, 30b are pressed by the pressing pins 66a against the first wall surface 64d1 so that the heat radiating surfaces 30a1, 30b1 are brought into contact with the first wall surface 64d1. Thus, the heat radiating surfaces 30a1, 30b1 are close contact with the first wall surface 64d1, and a gap is hardly generated between them. Similarly, the second heat sinks 22a, 22b are pressed by the pressing pins 66a against the second wall surface 64d2 so that the heat radiating surfaces 22a1, 22b1 are brought into contact with the second wall surface 64d2. Thus, the heat radiating surfaces 22a1, 22b1 are close contact with the second wall surface 64d2, and a gap is hardly generated between them. Thus, the semiconductor device 10 having the both-surface heat radiating structure in which the heat radiating surfaces 30a1, 30b1 are substantially flush with the surface 16a, and the heat radiating surfaces 22a1, 22b1 are substantially flush with the rear surface 16b can be obtained.

### Second Embodiment

In the present embodiment, a description of a part in common with the manufacturing method of the semiconductor device 10 described in the first embodiment will be omitted.

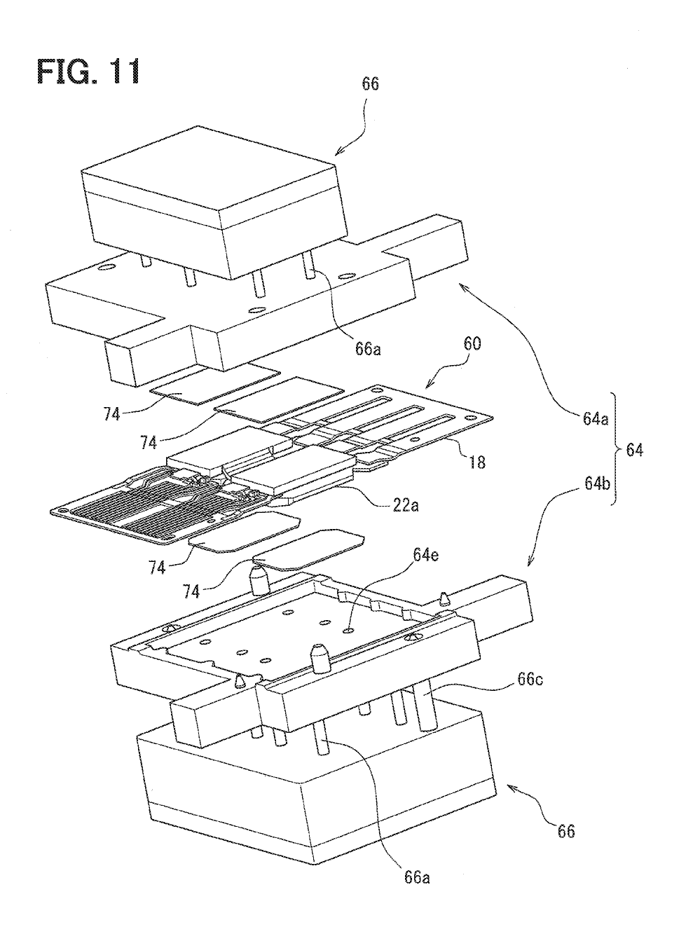

As shown in FIG. 11, in the present embodiment, in the second reflow process, insulating members 74 having electrical insulation property are disposed between the first wall surface 64d1 and the heat radiating surfaces 30a1, 30b1 of the first heat sinks 30a, 30b, and between the second wall surface 64d2 and the heat radiating surfaces 22a1, 22b1 of the second heat sinks 22a, 22b.

Then, the first heat sinks 30a, 30b with the insulating members 74 are pressed by the pressing pins 66a against the first wall surface 64d1. In addition, the second heat sinks 22a, 22b with the insulating members 74 are pressed by the pressing pins 66a against the second wall surface 64d2. Then, in this pressing state, the insulating members 74 are connected to the corresponding heat sinks 22a, 22b, 30a, 30b by the heat of the reflow. In the present embodiment, the insulating members 74 include a thermoplastic resin, and the insulating members 74 having sheet shapes are attached to the corresponding heat sinks 22a, 22b, 30a, 30b by the heat of the reflow.

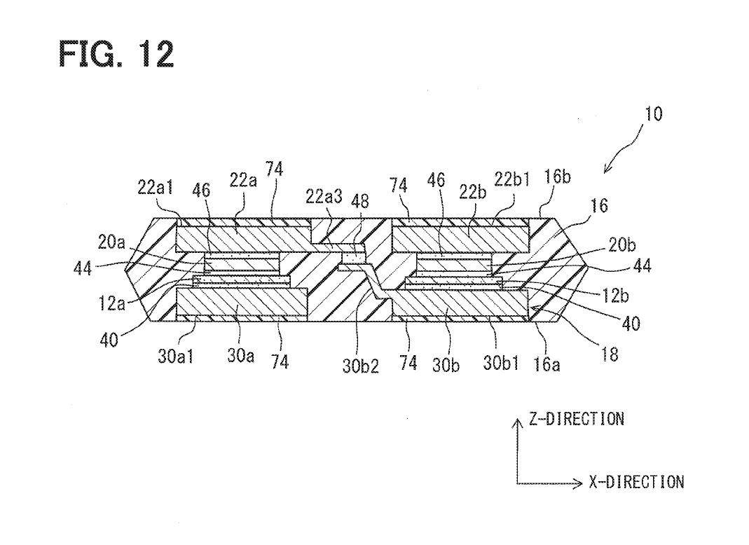

When the above-described molding process is carried out using the laminated body 62 connected with the insulating members 74, as shown in FIG. 12, the semiconductor device 10 in which each of the heat radiating surfaces 22a1, 22b1, 30a1, 30b1 are exposed from the resin molded body 16 and the heat radiating surfaces 22a1, 22b1, 30a1, 30b1 are connected with the insulating members 74 can be obtained.

Next, effects of the manufacturing method of the semiconductor device according to the present embodiment will be described.

According to the present embodiment, the insulating members 74 are connected with the heat radiating surfaces 22a1, 22b1, 30a1, 30b1. Thus, in a case where the heat is radiated from the heat radiating surfaces 22a1, 22b1, 30a1, 30b1 of the semiconductor device 10 to cooling devices which are not shown, insulation with the cooling devices can be secured by the semiconductor device 10 alone.

In addition, in the second reflow process, the insulating members 74 are connected with the heat radiating surfaces 22a1, 22b1, 30a1, 30b1. Thus, because the insulating members 74 need not be connected to the semiconductor device 10 after forming, the number of manufacturing processes can be reduced.

In the present embodiment, an example in which the insulating members 74 are connected to all of the heat radiating surfaces 30a1, 30b1 of the first heat sinks 30a, 30b and the heat radiating surfaces 22a1, 22b1 of the second heat sinks 22a, 22b is described. However, a configuration in which the insulating members 74 are provided to the first heat sinks 30a, 30b or the second heat sinks 22a, 22b can also be employed. Furthermore, a configuration in which the insulating member 74 is connected to only one of the heat radiating surfaces 22a1, 22b1, 30a1, 30b1 can also be employed.

While the present disclosure has been described with reference to embodiments thereof, it is to be understood that the disclosure is not limited to the embodiments and constructions. The present disclosure is intended to cover various modification and equivalent arrangements.

In the above-described embodiment, an example in which the semiconductor device 10 includes the terminals 20a, 20b is described. However, a configuration without the terminals 20a, 20b can also be employed. For example, projections corresponding to the terminals may be provided to the second heat sinks 22a, 22b. In this case, the solder 44 is also unnecessary.

In the above-described, the first reflow process, the wire bonding process, and the second reflow process are carried out in the stated order. In other words, the reflow is divided into the first reflow process and the second reflow process. However, the first reflow process and the second reflow process may be carried out together.

In the above-described embodiment, an example in which the main terminals 32 include two output terminals 32o1, 32o2 is described. However, a configuration in which one of the output terminals 32o1, 32o2 is provided, that is, only one output terminal is provided can also be employed.

In the above-described embodiment, an example in which the semiconductor device 10 includes the semiconductor chips 12a, 12b for one phase in the three-phase inverter is described. In other words, an example of 2-in-1 package is described. However, a semiconductor device of so-called 1-in-1 package in which only the semiconductor chip 12a is provided can also be employed. In addition, a semiconductor device of so-called 6-in-1 package in which the semiconductor chips 12a, 12b for three phases are provided can also be employed.

In the above-described embodiment, an example in which the passive components 24 are mounted to the surface 18a of the lead frame 18 is described. However, the passive components 24 may be mounted to the rear surface 18b.

In the above-described embodiment, an example in which the pressing unit 66 includes the pressing pins 66c is described. However, the pressing unit 66 may have a configuration without the pressing pins 66c. In this case, for example, a predetermined number of pressing pins 64f are provided to the lower mold 64b.

The number of the pressing pins 66a and the positions of the pressed portions 68 are not limited to the example in the above-described embodiment. The first heat sinks 30a, 30b only have to be pressed against the first wall surface 64d1 by the pressing pins 66a protruding from the lower mold 64b side to the cavity 64c, and the second heat sinks 22a, 22b only have to be pressed against the second wall surface 64d2 by the pressing pins 66a protruding from the upper mold 64a side to the cavity 64c. Needless to say that a stable pressing can be achieved by dispersing the pressing pins 66a.

The pressing unit 66 may constitute a part of the molding machine 72. In other words, the pressing unit 66 is not removed from the metal mold 64 after the reflow process, and the pressing unit 66 may be used also in the molding process. In this case, the pressing pins 66a may also serve as the ejector pins 72a.

1. A semiconductor device manufacturing method comprising:
disposing a first heat sink to one surface of a semiconductor chip, disposing a second heat sink to a rear surface opposite to the surface, and carrying out a reflow of a solder between the semiconductor chip and the first heat sink and a solder between the semiconductor chip and the second heat sink to form a laminated body in which the first heat sink, the second heat sink, and the semiconductor chip are integrated; and
disposing the laminated body in a cavity of a mold, and injecting a resin in the cavity in a state where the mold is closed in a laminating direction of the laminated body to form a resin molded body that seals the laminated body, wherein
the mold includes, as a wall surface defining the cavity, a first wall surface that faces a heat radiating surface of the first heat sink opposite to the semiconductor chip in the laminating direction and a second wall surface that faces a heat radiating surface of the second heat sink opposite to the semiconductor chip in the laminating direction,
the forming the laminated body includes:
attaching a pressing unit that includes a pressing pin and is configured to protrude the pressing pin into the cavity through a hole provided in the mold to the mold;
disposing the semiconductor chip, the first heat sink, the second heat sink, and the solders in the cavity and making a mold closing state;
pressing the first heat sink against the first wall surface and pressing the second heat sink against the second wall surface by the pressing pin in the mold closing state to make a pressing state; and
carrying out the reflow in the pressing state to form the laminated body, and
after forming the laminated body, the pressing pin is pulled out from the cavity and the resin molded body is formed.

2. The semiconductor device manufacturing method according to claim 1, wherein the forming the laminated body includes:
disposing an insulating member having an electrical insulation property at least one of between the first wall surface and the heat radiating surface of the first heat sink and between the second wall surface and the heat radiating surface of the second heat sink; and
connecting the insulating member to the corresponding heat sink by a heat of the reflow in a state where the corresponding heat sink with the insulating member is pressed against the wall surface by the pressing pin.

3. The semiconductor device manufacturing method according to claim 1, wherein the forming the laminated body includes:
bring the heat radiating surface of the first heat sink into contact with the first wall surface and bring the heat radiating surface of the second heat sink into contact with the second wall surface by pressing with the pressing pin to make the pressing state; and
carrying out the reflow in the pressing state.
